(19) United States
(12) Patent Application Publication
(10) Pub. No.: US 2026/0164832 A1
(43) Pub. Date: Jun. 11, 2026

(54) IMAGE SENSOR

(71) Applicant: Samsung Electronics Co., Ltd., Suwon-si (KR)

(72) Inventors: Kyongsoon CHO, Suwon-si (KR); Sanguk KIM, Suwon-si (KR); Dusik JUNG, Suwon-si (KR)

(73) Assignee: Samsung Electronics Co., Ltd., Suwon-si (KR)

(21) Appl. No.: 19/179,745

(22) Filed: Apr. 15, 2025

(30) Foreign Application Priority Data
Jul. 11, 2024 (KR) 10-2024-0091792

(51) Int. Cl. H10F 39/00

(52) U.S. Cl. CPC H10F 39/811; H10F 39/804; H10F 39/8053; H10F 39/8063; H10F 39/809

(57) ABSTRACT

An image sensor includes a first chip including a pixel array region, a pad region, and an inter-chip connection region between the pixel array region and the pad region, a second chip on a lower surface of the first chip, a plurality of through-via structures extending into the second chip through the first chip in the inter-chip connection region, a microlens layer including microlenses on a color filters, a first protective layer disposed on at least the inter-chip connection region, and having a plurality of first patterns each covering at least one of the plurality of through-via structures, and a second protective layer disposed on the microlens layer and the first protective layer, and having a plurality of second patterns respectively positioned on the plurality of first patterns.

### CROSS-REFERENCE TO RELATED APPLICATION(S)

This application claims the benefit under 35 USC 119 (a) of Korean Patent Application No. 10-2024-0091792 filed on Jul. 11, 2024 in the Korean Intellectual Property Office, the entire disclosure of which is incorporated herein by reference for all purposes.

### BACKGROUND

Some example embodiments relate to an image sensor and/or an image sensor package.

An image sensor is or includes a semiconductor-based sensor receiving light and generating an electric signal, and may include a pixel array having a plurality of pixels, a logic circuit for driving the pixel array and generating an image, and the like. Each of the pixels may include a photodiode and a pixel circuit for converting a charge generated by the photodiode into an electric signal.

### SUMMARY

Some example embodiments provide an image sensor having improved reliability.

According to some example embodiments, an image sensor includes a first chip including a pixel array region, a pad region, and an inter-chip connection region between the pixel array region and the pad region; a second chip on a lower surface of the first chip; a plurality of through-via structures extending into the second chip by penetrating through the first chip in the inter-chip connection region of the first chip; a surface insulating layer on the first chip; color filters on the surface insulating layer within the pixel array region of the first chip; a microlens layer including microlenses on the color filters; a first protective layer on at least the inter-chip connection region of the first chip, and having a plurality of first patterns each covering at least one of the plurality of through-via structures; and a second protective layer disposed on the microlens layer and the first protective layer, and having a plurality of second patterns respectively positioned on the plurality of first patterns in the inter-chip connection region of the first chip.

Alternatively or additionally according to some example embodiments, an image sensor includes a first substrate including a pixel array region in which photoelectric conversion devices are disposed, a pad region, and an inter-chip connection region between the pixel array region and the pad region, and having a first surface including a light-receiving surface of the photoelectric conversion devices, and a second surface opposite to the first surface; a first interconnection structure including a first wiring and a first inter-wiring insulating film on the second surface of the first substrate; a second substrate including a third surface opposite to the second surface and a fourth surface opposite to the third surface on the first interconnection structure; a second interconnection structure contacting the first interconnection structure on the third surface of the second substrate and including a second wiring and a second inter-wiring insulating film; a plurality of through-via structures penetrating through the first substrate and the first interconnection structure, extending into the second interconnection structure and electrically connected to the second wiring, the plurality of through-via structures in the inter-chip connection region; a surface insulating layer on the first surface of the first substrate; color filters on the surface insulating layer within the pixel array region of the first substrate; a microlens layer including microlenses on the color filters; a first protective layer integrated with the microlens layer and extending over the inter-chip connection region and the pad region, and having a plurality of first patterns each covering at least one of the plurality of through-via structures; and a second protective layer on the microlens layer and the first protective layer, and having a plurality of second patterns respectively positioned on the plurality of first patterns and isolated from each other.

Alternatively or additionally according to some example embodiments, an image sensor includes a first chip including a pixel array region, a pad region, and an inter-chip connection region between the pixel array region and the pad region; a second chip on a lower surface of the first chip; a plurality of through-via structures extending into the second chip by penetrating through the first chip in the inter-chip connection region of the first chip; a surface insulating layer on the first chip; color filters on the surface insulating layer within the pixel array region of the first chip; a microlens layer including microlenses on the color filters; a first protective layer on the inter-chip connection region and the pad region of the first chip; and a second protective layer on the microlens layer and the first protective layer. In the inter-chip connection region, the first and second protective layers have a plurality of patterns each covering at least one of the plurality of through-via structures.

### BRIEF DESCRIPTION OF DRAWINGS

The above and other aspects, features, and advantages of some example embodiments will be more clearly understood from the following detailed description, taken in conjunction with the accompanying drawings, in which:

FIG. 1 is a schematic exploded perspective view illustrating an image sensor according to some example embodiments;

FIG. 2 and FIG. 3 are cross-sectional views of the image sensor of FIG. 1 taken along lines I-I′ and II-II′, respectively;

FIG. 4 and FIG. 5 are cross-sectional views of the image sensor of FIG. 1 taken along lines III-III′ and IV-IV′, respectively;

FIG. 6 is a plan view illustrating an inter-chip connection region of the image sensor of FIG. 1;

FIG. 7A to FIG. 7C are plan views illustrating protective layer pattern arrays of image sensors according to various example embodiments;

FIG. 8 illustrates cross-sectional views illustrating image sensor packages according to various example embodiments; and

FIG. 9 to FIG. 12 are cross-sectional views illustrating image sensors according to various embodiments.

### DETAILED DESCRIPTION

Hereinafter, some example embodiments will be described with reference to the accompanying drawings.

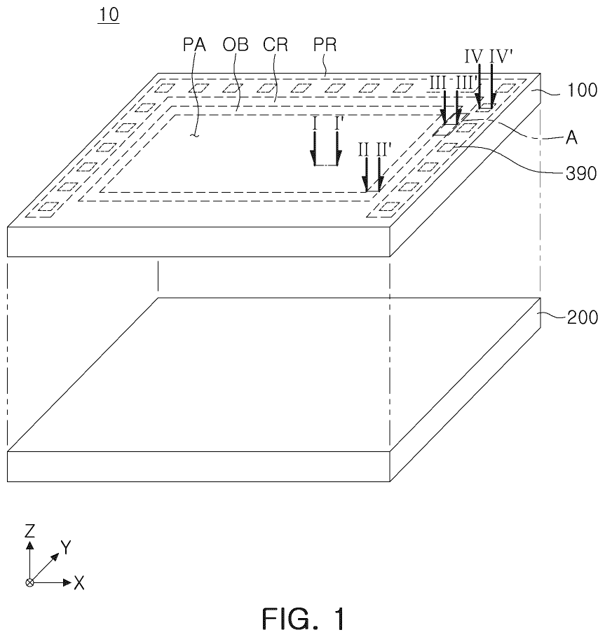

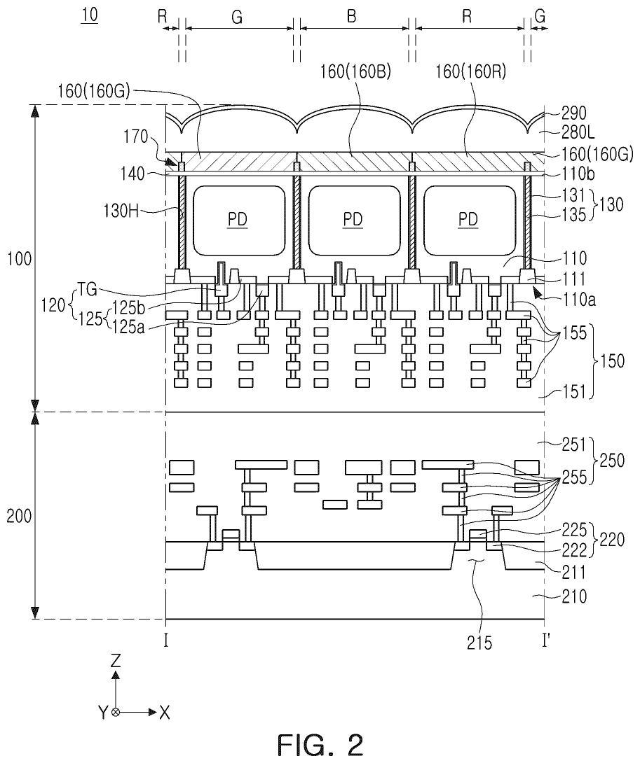

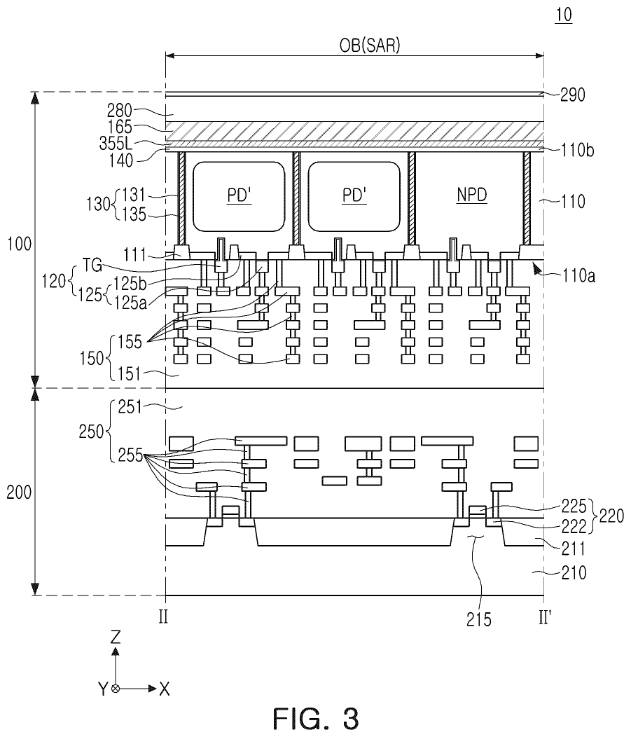

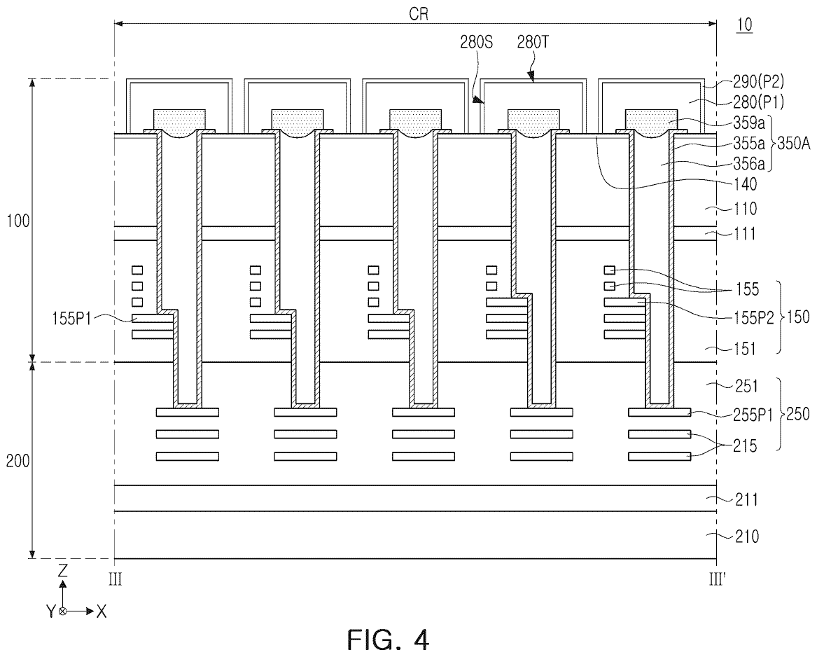

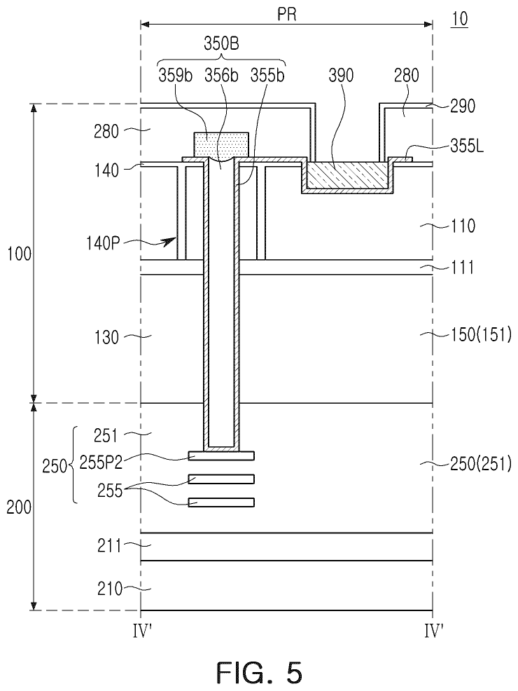

FIG. 1 is a schematic exploded perspective view illustrating an image sensor according to some example embodiments, and FIGS. 2 to 5 are schematic cross-sectional views illustrating an image sensor according to some example embodiments. FIGS. 2 and 3 are cross-sectional views of the image sensor of FIG. 1 taken along lines I-I′ and II-II′, respectively, and FIGS. 4 and 5 are cross-sectional views of the image sensor of FIG. 1 taken along lines III-III′ and IV-IV′, respectively.

Referring to FIG. 1, an image sensor 10 may include a first chip 100 and a second chip 200 that are stacked and electrically connected to each other.

The first chip 100 includes a pixel array region PA in which a plurality of pixels are disposed in a two-dimensional array structure, and the second chip 200 includes a logic area LA in which logic elements are disposed. The logic elements included in the logic area LA are electrically connected to the pixels of the pixel array region, and may provide signals to the pixels or process signals output from the pixels. For example, the logic area LA may include at least one of a control register block, a timing generator, a ramp signal generator, a row driver, a readout circuit, and a buffer. In some example embodiments, the first chip 100 may have the same size and/or shape as the second chip 200; example embodiments are not limited thereto.

Referring to FIG. 1, the first chip 100 may include a light-blocking region OB, an inter-chip connection region CR, and a pad region PR, arranged in order from the pixel array region PA. The pixel array region PA and the light-blocking region OB may also be referred to as a sensor array region SAR.

The pixel array region PA may have active pixels arranged that receive light and generate an active signal. The light-blocking region OB may have optical black pixels arranged that block light and may be configured to generate an optical black signal. The light-blocking region OB may be arranged along the periphery of the pixel array region PA, for example, but this is merely illustrative. In some example embodiments, dummy pixels may be disposed in the pixel array region PA adjacent to the light-blocking region OB.

The inter-chip connection region CR may be disposed around the sensor array region, particularly the light-blocking region OB. The inter-chip connection region CR may be disposed on at least one side of the light-blocking region OB, but this is merely illustrative, and may be disposed across all four corners, as in example embodiments illustrated with respect to FIG. 1. Wires may be disposed in the inter-chip connection region CR and may be configured to transmit and receive electrical signals of the sensor array region SAR.

The pad region PR may be disposed around the inter-chip connection region CR. In some example embodiments, the pad region PR may be disposed adjacent to the edge of the image sensor 10. In some example embodiments, the pad region PR is illustrated as being disposed along the four edges of the image sensor 10, but may be disposed at the opposite edges or may be disposed to surround almost the entirety of the first chip 100. The pad region PR includes a plurality of pads for connection with an external device, and may be configured to transmit and receive electrical signals between the image sensor 10 and the external device.

In some example embodiments, the inter-chip connection region CR is located between the sensor array region SAR and the pad region PR, but this is only an example. The arrangement of the pixel array region PA, the light-blocking region OB, the inter-chip connection region CR, and the pad region PR may be variously changed as needed or desired.

FIGS. 2 to 5 are cross-sectional views taken along lines I-I′, II-II′, III-III′, and IV-IV′ of the image sensor of FIG. 1, respectively.

Referring to FIGS. 2 to 5, the first chip 100 of the image sensor 10 according to some example embodiments may include a first substrate 110 having a lower surface 110a and an upper surface 110b, a device isolation film 111 defining an active area on the lower surface 110a of the first substrate 110, first circuit elements 120 on the active area of the lower surface 110a of the first substrate 110, and a first interconnection structure 150 between the lower surface of the first substrate 110 and the second chip 200. The upper surface 110b of the first substrate 110 may be referred to as the first surface or back side, and the lower surface 110a of the first substrate 110 may be referred to as the second surface or front side. The upper surface 110b of the first substrate 110 may be a light-receiving surface on which light is incident. The image sensor according to some example embodiments may be or may include a back-side illumination (BSI) image sensor. A number of layers of the first interconnection structure 150 may be the same as or different from the number of layers of the first interconnection structure 150 illustrated in FIG. 2.

As illustrated in FIG. 2, in the pixel array region PA, the first chip 100 may include a surface insulating layer 140 on the upper surface 110b of the first substrate 110, a grid pattern 170 on the surface insulating layer 140, color filters 160 covering the surface insulating layer 140 and the grid pattern 170, and microlenses 280L on the color filters 160. In addition, the first chip 100 may further include, as illustrated in FIG. 3, a conductive layer 355L on a horizontal insulating layer 140, a light-blocking layer 165 on the conductive layer 355L, and a first protective layer 280 and a second protective layer 290 covering the light-blocking layer 165 in the light-blocking region OB.

The second chip 200 may be placed on the lower surface of the first chip 100. Referring to FIGS. 2 and 3, the second chip 200 may include a second substrate 210, a device isolation film 211 defining an active area 215 on the second substrate 210, second circuit elements 220 on the second substrate 210, and a second interconnection structure 250 electrically connected to the second circuit elements 220. The logic elements 220 may include elements such as transistors including a gate 225 and a source/drain 222. A number of layers of the second interconnection structure 250 may be the same as, or different from, the number of layers of the second interconnection structure 250 illustrated in FIG. 2. Alternatively or additionally, the gates 225 may be arranged to extend in the Y direction and/or the X direction; example embodiments are not limited thereto.

The first substrate 110 may be or may include a semiconductor substrate. For example, the first substrate 110 may be bulk silicon or a silicon-on-insulator (SOI). The first substrate 110 may be a silicon substrate, and/or may include other materials, such as one or more of silicon-germanium (SiGe), indium antimonide, lead telluride, indium arsenide, indium phosphide, gallium arsenide, or gallium antimonide. Alternatively or additionally, the first substrate 110 may have a structure in which an epitaxial layer is formed on a base substrate. A plurality of unit pixels may be disposed on the first substrate 110 in the sensor array region SAR. For example, a plurality of pixels may be formed in a two-dimensional for example, matrix arrangement in a plane including a first direction X and a second direction Y within the pixel array region PA.

Each unit pixel may include photoelectric conversion devices PD. The photoelectric conversion devices PD may be disposed within the first substrate 110 of the pixel array region PA. The photoelectric conversion devices PD may generate charges in proportion to an amount of light incident from the outside. For example, the photoelectric conversion devices PD may include at least one of a photo diode, a photo transistor, a photo gate, a pinned photo diode, an organic photo diode, a quantum dot, and combinations thereof, but are not limited thereto.

The first circuit elements 120 may include a transfer gate TG and active elements 125. The active elements 125 may each include a gate 125a and a source/drain 125b. The transfer gate TG may transfer charges from an adjacent photoelectric conversion device PD to an adjacent floating diffusion region, and the active elements 125 may be transistors connected to the photoelectric conversion device PD to process electrical signals, and may be or included at least one of a source follower transistor, a reset transistor, and a selection transistor. The transfer gate TG may be a or may include vertical transfer gate (VTG) that includes a portion extending from the lower surface 110a of the first substrate 110 into the first substrate 110.

The pixel separation pattern 130 may be disposed within the first substrate 110 of the sensor array region SAR. The pixel separation pattern 130 may define a plurality of unit pixels. The pixel separation pattern 130 may be disposed to surround each photoelectric conversion device PD. The pixel separation pattern 130 may be disposed in a grid shape in a planar view and separate a plurality of pixels from each other.

In some example embodiments, the pixel separation pattern 130 may penetrate at least a portion of the first substrate 110. In some example embodiments, the pixel separation pattern 130 may include a trench 130H extending from the lower surface 110a to the upper surface 110b, and may have a structure in which an insulating material is buried in the trench 130H. The pixel separation pattern 130 may include a separation insulating layer 131 formed on the sidewall of the trench 130H, and a filling portion 135 surrounded by the separation insulating layer 131. For example, the separation insulating layer 131 may include silicon oxide, and the filling portion 135 may include polysilicon.

In some example embodiments, the pixel separation pattern 130 may be connected to the device isolation film 111. As described above, the device isolation film 111 is placed on the lower surface 110a of the first substrate 110 and may define an active area. For example, the device isolation film 111 may include an insulating material such as silicon oxide.

Meanwhile, referring to FIG. 3, a first reference region or dummy photoelectric conversion devices PD′ formed in the same manner as, e.g., at the same time as, the photoelectric conversion devices PD and a second reference region NPD in which the photoelectric conversion devices PD are not formed may be provided in the light-blocking region OB. The second reference region NPD may be a comparison region that does not include the photoelectric conversion devices PD or a comparison region that does not include the photodiode of the photoelectric conversion devices PD. For example, the dummy photoelectric conversion devices PD′ may be disposed in the first substrate 110 of the light-blocking region OB adjacent to the pixel array region PA, but may not be disposed in the first substrate 110 of the light-blocking region OB spaced apart from the pixel array region PA. In the light-blocking region OB, the first and second reference areas PD′, NPD may be disposed within the first substrate 110 and may be isolated by the pixel separation pattern 130.

The first interconnection structure 150 may be disposed on the lower surface of the first substrate 110. The first substrate 110 and the first interconnection structure 150 may constitute the first chip 100, where the first chip 100 may also be referred to as a ‘sensor chip’.

The first interconnection structure 150 may include a first inter-wiring insulation layer 151 and a plurality of first wirings 155 on the first inter-wiring insulation layer 151. The number of layers and/or the arrangements of the wirings constituting the first interconnection structure 150 illustrated in the drawing are merely illustrative. The plurality of first wirings 155 may include wiring patterns on different levels and vias electrically connecting the wiring patterns and the first circuit elements 120. The first inter-wiring insulating layer 151 may independently include at least one of, for example, silicon oxide, silicon nitride, silicon oxynitride, and a low-K material having a lower dielectric constant than silicon oxide. The first wirings 155 may independently include at least one of, for example, tungsten (W), copper (Cu), aluminum (Al), gold (Au), silver (Ag), and alloys thereof.

Similar to the first substrate 110, the second substrate 210 may be or may include bulk silicon or a silicon-on-insulator SOI. The second substrate 210 may be or include a silicon substrate, or may include other materials, such as one or more of silicon germanium, indium antimonide, lead telluride, indium arsenide, indium phosphide, gallium arsenide, or gallium antimonide. Alternatively or additionally, the second substrate 210 may be or may include an epi layer formed on a base substrate. Second circuit elements 220 may be disposed on the second substrate 210. For example, the second circuit elements 220 may include transistors that constitute or are included in one or more of a control register block, a timing generator, a ramp signal generator, a row driver, a readout circuit, or a buffer.

The second interconnection structure 250 may be disposed on the second substrate 210. For example, the second interconnection structure 250 may be disposed between the first interconnection structure 150 of the first chip 100 and the second substrate 210. The second substrate 210 and the second interconnection structure 250 may constitute a second chip 200. In this case, the second chip 200 may also be referred to as a “logic chip.” The second interconnection structure 250 may include a second inter-wiring insulation layer 251 and a plurality of second wirings 255 on the second inter-wiring insulation layer 251. The number of layers and/or the arrangements of the wirings constituting the second interconnection structure 250 illustrated in the drawing are merely illustrative. The plurality of second wirings 255 may include wiring patterns on different levels and vias electrically connecting the wiring patterns and the second circuit elements 220. The second interconnection structure 250 may provide a path for transmitting and receiving electrical signals between the second circuit elements 220 and each unit pixel of the sensor array region SAR. The second inter-wire insulating layer 251 may include at least one of, for example, silicon oxide, silicon nitride, silicon oxynitride, and a low-K material having a lower dielectric constant than silicon oxide. The second wires 255 may independently or concurrently include at least one of, for example, tungsten (W), copper (Cu), aluminum (Al), gold (Au), silver (Ag), and alloys thereof. In some example embodiments, the first interconnection structure 150 may be bonded to the second interconnection structure 250. In some example embodiments, a bonding insulating film may be included at the interface of the first and second interconnection structures 150, 250. The bonding insulating film may include at least one of, but is not limited to, silicon oxide, silicon nitride, silicon oxynitride, and silicon carbonitride SiCN.

The surface insulating layer 140 may be disposed on almost the entire upper surface 110b of the first substrate 110. The surface insulating layer 140 may extend along the upper surface 110b of the first substrate 110 in the sensor array region SAR, as well as in the peripheral region, for example, the inter-chip connection region CR and the pad region PR. The surface insulating layer 140 may include an insulating material. For example, the surface insulating layer 140 may include at least one of silicon oxide, silicon nitride, silicon oxynitride, aluminum oxide, hafnium oxide, and combinations thereof.

In some example embodiments, the surface insulating layer 140 may be a multilayer. The surface insulating layer 140 may function as an antireflection film to prevent or reduce, e.g., reduce the impact from and/or occurrence of reflection of light incident on the first substrate 110, thereby improving the light reception rate of the photoelectric conversion device PD. Alternatively or additionally, the surface insulating layer 140 functions as a flattening film or a planarization film, so that the color filter 160 and the microlens layer 280L described later may be formed at a uniform height. For example, the surface insulating layer 140 may include an aluminum oxide film, a hafnium oxide film, a silicon oxide film, a silicon nitride film, and a hafnium oxide film, which are sequentially laminated on the upper surface 110b of the first substrate 110.

The color filter 160 may be disposed on the surface insulating layer 140. The color filter 160 may be arranged to correspond to respective unit pixels of the pixel array region PA. The color filter 160 may have various color filters depending on the unit pixel. For example, the color filter 160 may include a red color filter 160R, a green color filter 160G, and a blue color filter 160B. In some example embodiments, the color filters 160 may be arranged in a Bayer pattern. However, this is only an example, and the color filters 170 may include a yellow filter, a magenta filter, and a cyan filter, and may further include a white filter.

In some example embodiments, a grid pattern 170 may be disposed between the color filters 160. The grid pattern 170 may be disposed on the surface insulating layer 140. The grid pattern 170 may be interposed between the color filters 160. In some example embodiments, the grid pattern 170 may be disposed to overlap the pixel separation pattern 130 in the third direction Z which is vertical. In some example embodiments, the grid pattern 170 may include a conductive pattern and a low refractive index pattern. The conductive pattern may effectively prevent or reduce ESD failure by preventing charges generated by ESD, etc. from accumulating on the surface of the first substrate 110. The low refractive index pattern may improve the light collection efficiency by refracting or reflecting light incident obliquely, thereby improving the quality of the image sensor. For example, the conductive pattern may include at least one of titanium (Ti), titanium nitride (TiN), tantalum (Ta), tantalum nitride (TaN), tungsten (W), aluminum (Al), and copper (Cu), and the low refractive index pattern may include a low refractive index material having a lower refractive index than silicon Si. For example, the low refractive index pattern may include at least one of silicon oxide, aluminum oxide, tantalum oxide, and combinations thereof.

The microlens layer 280L may be disposed on the color filter 160. The microlens layer 280L may include microlenses arranged to correspond to each unit pixel of the pixel array region PA. Each of the microlenses has a convex shape and may have a radius, e.g., a predetermined radius of curvature. Accordingly, the microlens may focus light incident on the photoelectric conversion devices PD. The microlens layer 280L may include, for example, a light-transmitting resin. In some example embodiments, the microlens layer 280L may extend to a portion of the peripheral area for example, the light-blocking region OB.

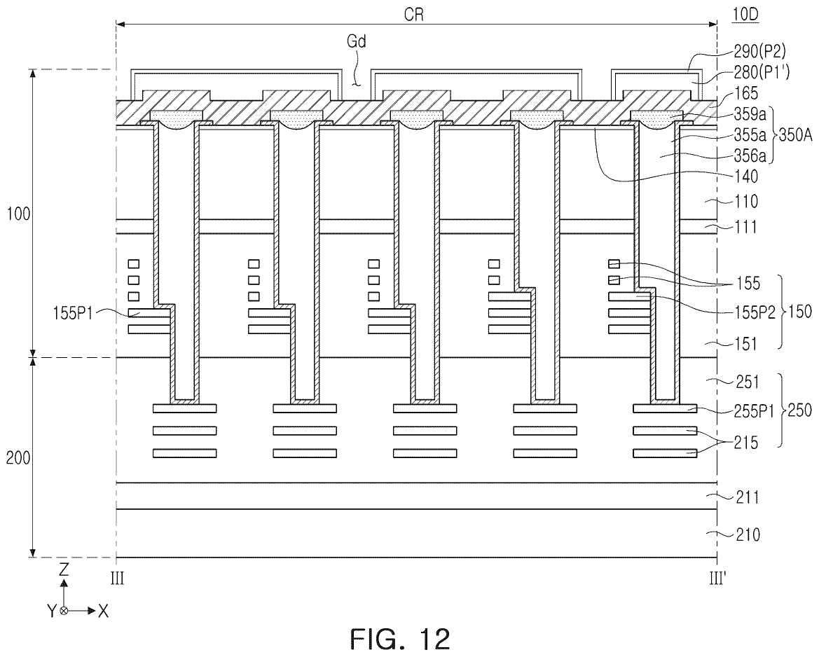

Referring to FIG. 3, the first chip 100 may further include a light-blocking filter layer 165. The light-blocking filter layer 165 may be disposed on the conductive layer 355L in the light-blocking region OB. In some example embodiments, the light-blocking filter layer 165 may extend from the light-blocking region OB to at least a portion of the inter-chip connection region CR on the conductive layer 355L (see FIG. 12), but is not limited thereto.

The light-blocking filter layer 165 may form a light-blocking pattern that blocks or at least partially blocks light together with the conductive layer 355L. The light-blocking filter layer 165 may be formed together with the color filters 160 and have substantially the same thickness as the color filters 160, but is not limited thereto. The light-blocking filter layer 165 may include a blue color filter and/or a black filter.

In some example embodiments, the light-blocking area OB may be used to remove or at least partially remove a noise signal due to dark current. For example, in a state where light is blocked by the conductive layer 355L and the light-blocking filter layer 165, the first reference area PD′ including the photodiode may be used as a reference pixel for noise removal by the photodiode. In addition, in a state where light is blocked by the conductive layer 355L and the light-blocking filter layer 165, the second reference area NPD that does not include the photodiode may be an area for checking process noise for noise removal by components other than the photodiode.

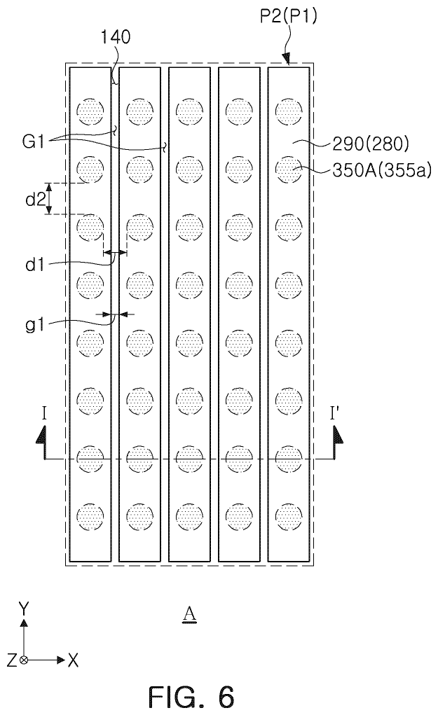

The image sensor 10 according to some example embodiments may include a plurality of through-via structures 350A that extend into the second chip 200 by penetrating a portion of the first chip 100 in the inter-chip connection region CR. The plurality of through-via structures 350A may be arranged in a first direction X and a second direction Y intersecting the first direction X in a planar view, as illustrated in FIG. 6.

In some example embodiments, the plurality of through-via structures 350A may each include a via conductive layer 355a, a filling insulating film 356a, and a capping pattern 359a. The via hole H1 may expose the first or second pad 155P1 or 155P2 of the first interconnection structure 150 and the first pad 255P1 of the second interconnection structure 250. A plurality of through-via structures 350A may be formed within each of the plurality of first via holes H1.

A via conductive layer 355a may be formed, e.g., conformally formed on a sidewall and a bottom surface of the first via hole H1 within the inter-chip connection region CR. The via conductive layer 355a may electrically connect the first or second pad 155P1 or 155P2 of the first interconnection structure 150 and the first pad 255P1 of the second interconnection structure 250. The via conductive layer 355a may be disposed within the first via hole H1 to connect the first wiring 155 and the second wiring 255. The via conductive layer 355a may extend along a profile of the sidewall and bottom surface of the first via hole H1.

In some example embodiments, the via conductive layer 355a is formed together with the conductive layer 355L extending from the upper surface 110b of the first substrate 110, and may be a layer connected to the conductive layer 355L or separated from the conductive layer 355L and other via conductive layers. For example, the via conductive layer 355a may include at least one of titanium (Ti), titanium nitride (TiN), tantalum (Ta), tantalum nitride (TaN), tungsten (W), aluminum (Al), copper (Cu), and combinations thereof.

In some example embodiments, the filling insulating film 356a may be disposed on the via conductive layer 355a to fill at least a portion of the first via hole H1. In some example embodiments, the upper surface of the filling insulating film 356a may be concave or may include a concave portion or dished portion. This may be due to the characteristics of the process of forming the filling insulating film 356a for example, deposition process and/or planarization process, but is not limited thereto. For example, the filling insulating film 356a may include a silicon-based insulating material, for example, one or more of silicon nitride, silicon oxide, and silicon oxynitride and a high-k material for example, hafnium oxide and aluminum oxide.

In some example embodiments, the capping pattern 359a may be disposed on the via conductive layer 355a and the filling insulating film 356a. For example, a portion of the capping pattern 359a may protrude from the upper surface of the via conductive layer 355a. In some example embodiments, the capping pattern 359a may be omitted.

The image sensor 10 according to some example embodiments further includes a first partially protective layer or a first protective layer 280 that extends from the microlens layer 280L and is disposed on the peripheral region, for example, the light-blocking region OB, the inter-chip connection region CR, and the pad region PR.

The first protective layer 280 may extend on the light-blocking region OB, the inter-chip connection region CR, and the pad region PR to provide a flat upper surface. In this case, the first protective layer 280 may also be referred to as a planarization layer. In some example embodiments, the first protective layer 280 may extend to cover the light-blocking filter layer 165 in the light-blocking region OB and the multiple through-via structures in the inter-chip connection region to provide a flat upper surface, and may extend on the pad region PR. The first protective layer 280 may be formed so that the bonding pad 390 is exposed in the pad region PR. In some example embodiments, the first protective layer 280 may be or may include a layer formed together on the light-blocking region OB, the inter-chip connection region CR, and the pad region PR in a deposition process for forming the microlens layer 280L of the pixel array region PA. The first protective layer 280 may include the same material as the microlens layer 280L. For example, the first protective layer 280 may include a light-transmitting resin such as a transparent photoresist material and/or a transparent thermosetting resin material.

The image sensor according to some example embodiments may further include a second protective layer 290 formed on the microlens layer 280L and the first protective layer 280. The second protective layer 290 may extend along the surface of the microlens layer 280L and may be formed on an upper surface of the first protective layer 280. The second protective layer 290 may be formed relatively conformally. The second protective layer 290 may have a thickness smaller than or less than that of the first protective layer 280. The second protective layer 290 may include a low temperature oxide LTO. The second protective layer 290 may include an inorganic oxide, such as, for example, one or more of silicon oxide, titanium oxide, zirconium oxide, hafnium oxide, or combinations thereof. The second protective layer 290 may protect the microlens layer 280L from the outside. For example, the second protective layer 290 may protect or at least partially protect the microlens layer 280L including an organic material by including an inorganic oxide film. Alternatively or additionally, the second protective layer 290 may improve the quality of the image sensor 10 by improving the light collection efficiency of the microlenses of the microlens layer 280L. For example, the second protective layer 290 may be formed in the area between the microlenses to reduce one or more of reflection, refraction, scattering, etc. of incident light reaching the space between the microlenses.

In the inter-chip connection region CR of the image sensor 10 according to some example embodiments, by isolating the first and second protective layers 280, 290 into a plurality of patterns P1 and P2, the influence of thermal stress may be reduced, e.g., may be significantly reduced, thereby effectively preventing or reducing the likelihood of and/or impact from damage such as cracks.

FIG. 6 is a plan view illustrating a part “A” of the inter-chip connection region CR of the image sensor of FIG. 1, and FIG. 4 may be understood as a cross-section obtained by cutting the plane of FIG. 6 in the X-direction.

Referring to FIG. 6 together with FIG. 4, a plurality of through-via structures 350A may be arranged in the first direction X and the second direction Y in the inter-chip connection region CR. The plurality of through-via structures 350A may be arranged at a first interval d1 in the first direction X and at a second interval d2 in the second direction Y.

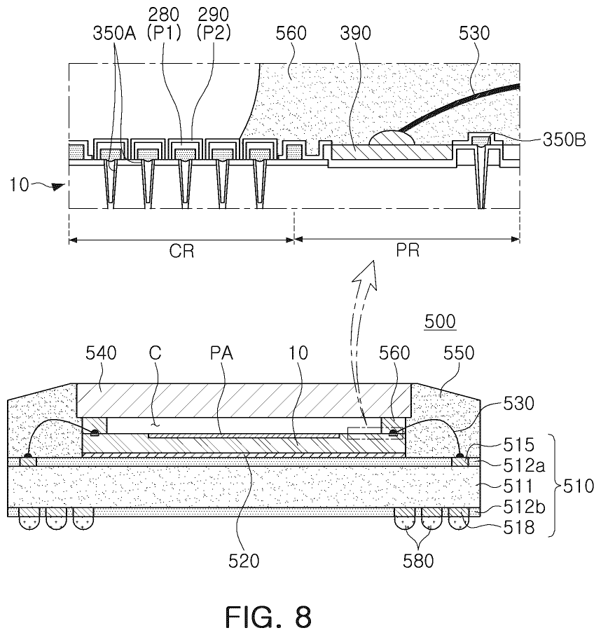

The first and second protective layers 280, 290 according to some example embodiments may be isolated by a groove G1 extending in the second direction Y from the first and second patterns P1 and P2, respectively. In this way, by reducing the unit area of the first and second protective layers 280, 290, the thermal stress applied to the first and second protective layers 280, 290 when in contact with an external structure such as a glue dam at the package level may be alleviated or at least partly alleviated (see FIG. 8).

The first protective layer 280 may have a plurality of first patterns P1 covering the through-via structures of each column arranged in the second direction Y among the plurality of through-via structures 350A. In addition, the second protective layer 290 may have a plurality of second patterns P2 corresponding to the plurality of first patterns P1 in the inter-chip connection region CR.

In some example embodiments, the plurality of first patterns P1 may be completely isolated from other first patterns. The plurality of second patterns P2 may be respectively disposed on the upper surface 280T of the plurality of first patterns P1 and may extend to the side surface 280S adjacent to the upper surface 280T. Alternatively or additionally, the plurality of second patterns P2 may each have patterns isolated from each other. A surface insulating layer 140 may be exposed between the plurality of first and second patterns P1 and P2, for example, at the bottom of the groove G1. In some example embodiments, a portion of the conductive layer 355L may be exposed at the bottom of the groove G1.

The first and second patterns P1 and P2 according to some example embodiments may be formed by performing a first etching process to separate the first protective layer 280 into a desired first pattern in the inter-chip connection region CR after forming a first protective layer 280 on the upper surface of the first chip 100, and then performing a second etching process to separate the second protective layer 290 into a second pattern corresponding to the first pattern in the inter-chip connection region CR after conformally forming a second protective layer 290 on the first protective layer 280 and the microlens layer 280L.

In the pad region PR, the bonding pad 390 may be connected to the pad via structure 350B by the conductive layer 355L. In some example embodiments, the pad via structure 350B may include a via conductive layer 355b, a filling insulating film 356b, and a capping pattern 359b, similar to the plurality of through-via structures 350A. The second via hole H2 may expose the second pad 255P2 of the second interconnection structure 250. The pad through-via structure 350B may be formed within each of the second via holes H2.

The via conductive layer 355b may be conformally formed on the sidewall and bottom surface of the second via hole H2 within the pad region PR. The via conductive layer 355b may electrically connect the second pad 255P2 of the second interconnection structure 250. The via conductive layer 355b may be disposed in the second via hole H2 and connected to the second wiring 255.

As illustrated in FIG. 5, the first substrate 110 may have a recess extending inward from the upper surface in the pad region PR. The via conductive layer 355b may extend to the upper surface of the surface insulating layer 140 and cover the sidewall and bottom surface of the recess. The bonding pad 390 may be disposed on the via conductive layer 355b within the recess. The bonding pad 390 may have a structure embedded in the recess portion of the first substrate 110.

In some example embodiments, the via conductive layer 355b may include at least one of titanium (Ti), titanium nitride (TiN), tantalum (Ta), tantalum nitride (TaN), tungsten (W), aluminum (Al), copper (Cu), and combinations thereof. For example, the filling insulating film 356b may include a silicon-based insulating material for example, silicon nitride, silicon oxide, and silicon oxynitride and a high-k material for example, hafnium oxide and aluminum oxide. The bonding pad 390 may include a conductive material other than the via conductive layer 355b, for example, aluminum (Al). The image sensor 10 according to some example embodiments may further include a separation pattern 140P penetrating the first substrate 110 within the pad region PR. In one example, the separation pattern 140P may extend from at least a portion of the surface insulating layer 140.

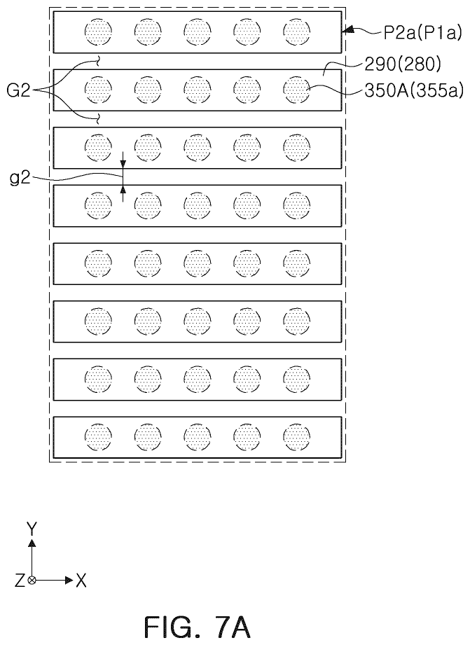

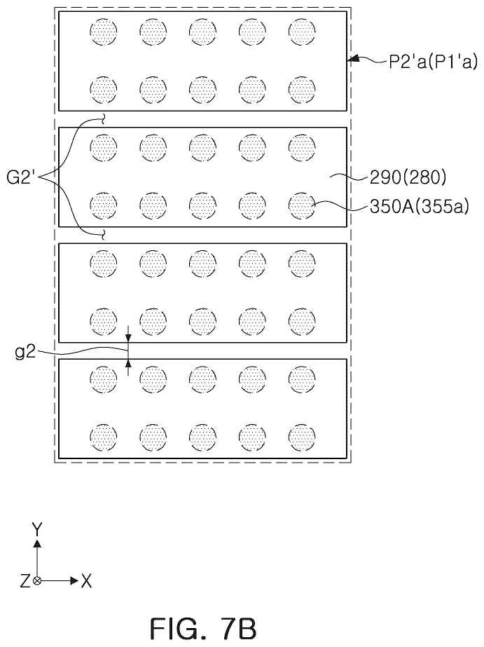

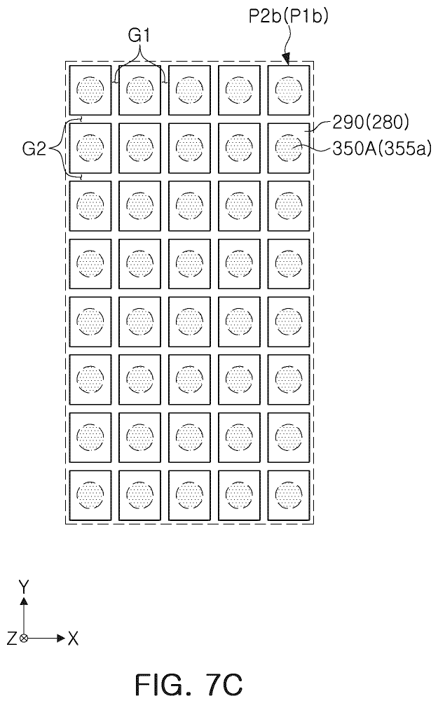

The image sensor 100 described above may be implemented in various modified examples. In particular, the first and second protective layers may be patterned in various shapes. FIGS. 7A to 7C are plan views illustrating protective layer pattern arrays of an image sensor according to various example embodiments.

Referring to FIG. 7A, the first and second protective layers 280, 290 according to some example embodiments may be isolated by a groove G2 extending in the first direction X as the first and second patterns P1a, P2a, respectively. The first protective layer 280 may have a plurality of first patterns P1a covering respective rows of through-via structures 350A arranged in the first direction X among the plurality of through-via structures 350A. Alternatively or additionally, the second protective layer 290 may have a plurality of second patterns P2a corresponding to each of the plurality of first patterns P1a in the inter-chip connection region CR.

Similar to the example illustrated in FIG. 6, the plurality of through-via structures 350A are arranged such that the spacing in the second direction Y is greater than the spacing in the first direction X, and the plurality of first and second patterns P1a, P2a may be isolated by grooves G2 along the first direction X.

In this way, by forming grooves G2 along relatively large intervals, the process of isolating the first and second protective layers 280, 290 into a plurality of first and second patterns P1a, P2a may be performed more easily. For example, the plurality of first and second patterns P1a, P2a employed in some example embodiments illustrated with reference to FIG. 7A may be isolated by a gap g2 larger than the gap g1 of various example embodiments illustrated with reference to FIG. 6.

Referring to FIG. 7B, the first and second protective layers 280, 290 according to some example embodiments may be isolated by a groove G2 extending in the first direction X into the first and second patterns P1′a, P2′a, respectively, similarly to the example illustrated in FIG. 7A. However, the first and second protective layers 280, 290 may have a plurality of first and second patterns P1′a, P2′a that cover the through-via structures in units of two rows, although they are arranged in the first direction X among the plurality of through-via structures 350A. In this manner, the first and second protective layers 280, 290 may be isolated into various patterns that cover the through-via structures 350A of a plurality of rows and/or columns, respectively.

Referring to FIG. 7C, the first and second protective layers 280, 290 according to some example embodiments may be isolated into first and second patterns Plb, P2b by a first groove G1 extending in the second direction Y and a second groove G2 extending in the first direction X, respectively. Accordingly, a plurality of first patterns Plb may be configured to cover one through-via structure 350A, respectively.

FIG. 8 is a cross-sectional view illustrating an image sensor package according to some example embodiments.

Referring to FIG. 8, the image sensor package 500 of some example embodiments may include a package substrate 510, an image sensor 10, a bonding wire 530, a transparent cover 540, an encapsulant 550, and a dam 560.

The package substrate 510 may include a substrate body 511, an upper pad 515, a lower pad 518, and upper and lower passivation layers 512a, 512b. For example, the substrate body 511 may include silicon, ceramic, organic matter, glass, epoxy resin, and the like. In some example embodiments, the package substrate 510 may be a printed circuit board PCB. The substrate body 511 may include single-layer or multi-layer wirings. The wires may electrically connect the upper pad 515 and the lower pad 518.

The upper pad 515 may be disposed along both sides of the image sensor 10 mounted on the package substrate 510. The lower pad 518 is disposed on the lower surface of the package substrate 510, and an external connection terminal 580, such as a solder ball, may be disposed on the lower pad 518.

The image sensor 10 may be mounted on the package substrate 510 with a wire bonding structure. The image sensor 10 is mounted with the pixel array region PA facing upward, and may be bonded to the package substrate 510 by an adhesive layer 520. The bonding pad 390 of the image sensor 10 may be electrically connected to the corresponding upper pad 515 of the package substrate 510 through the bonding wire 530.

A transparent cover 540 may be placed on the image sensor 10. A dam 560 may be placed on the area surrounding the image sensor 10, and the transparent cover 540 may be placed on the dam 560. The dam 560 may support the transparent cover 540 on the image sensor 10. The transparent cover 540 may be spaced apart from the upper surface of the image sensor 10 by the height of the dam 560. A space C may exist between the transparent cover 540 and the image sensor 100. For example, the transparent cover 540 may include one or more of transparent glass, transparent resin, or light-transmitting ceramic.

An encapsulant 550 may be placed on the package substrate 510 and may seal the image sensor 10, the bonding wire 530, and the transparent cover 540. In detail, the encapsulant 550 may be formed to cover the image sensor 10 and the side surface of the transparent cover 540 from the upper surface of the package substrate 510. Alternatively or additionally, the encapsulant 550 may cover the bonding wire 530 and the outer surface of the dam 560. In some example embodiments, the encapsulant 550 may have a side surface that is substantially coplanar with the side surface of the package substrate 510. For example, the encapsulant 550 may be formed of or may at least include Epoxy Molding Compound (EMC).

The dam 560 employed in some example embodiments may have a square ring shape that surrounds the peripheral area of the upper surface of the image sensor 10. The dam 560 may be placed in the peripheral area of the upper surface of the image sensor 10, for example, in the pad region PR. The dam 560 may be formed to cover the bonding pad 390 and bonding wire 530 of the image sensor 10. The dam 560 may extend to the inter-chip connection region CR and be bonded to the second protective layer 290. Due to the difference in thermal expansion coefficients between the first and second protective layers 280, 290, the dam 560 may apply thermal stress to the second protective layer 290, causing cracks in the second protective layer 290, resulting in appearance defects. Alternatively or additionally, the dam may be peeled off due to the cracks, and the reliability of the image sensor 10 may be degraded due to moisture or foreign substances from the outside.

To prevent or reduce the likelihood of and/or impact from defects due to such thermal stress, in the inter-chip connection region CR of the image sensor 10, the first and second protective layers 280, 290 are isolated into multiple patterns P1 and P2 to significantly reduce the influence of thermal stress and effectively prevent or reduce damage such as cracks

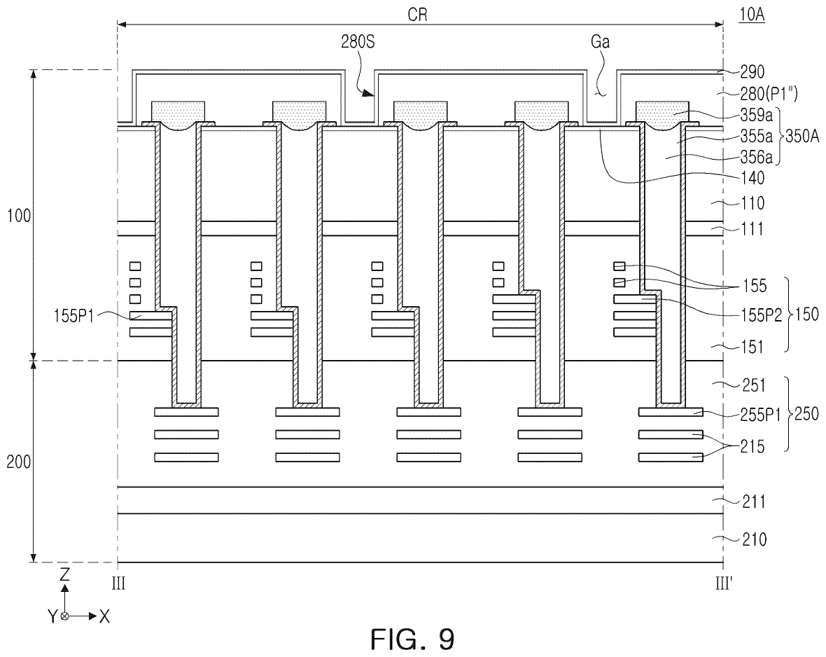

FIGS. 9 to 12 are cross-sectional views illustrating image sensors according to various embodiments. FIGS. 9 to 12 are cross-sectional views of the inter-chip connection region CR of image sensors 10A, 10B, 10C and 10D according to various example embodiments, and may be understood as cross-sections corresponding to FIG. 4.

Referring to FIG. 9, an image sensor 10A according to some example embodiments may be understood to have a structure similar to the image sensor 10 illustrated in FIGS. 1 to 6, in detail, FIG. 4, except that the first protective layer 280 is composed of a first pattern P1″ covering two or two columns of through-via structures 350A in the inter-chip connection region CR, and the second protective layer 290 is not isolated but formed as a single layer. In addition, the components of some example embodiments may be understood by referring to the description of the same or similar components of the image sensor 10 illustrated in FIGS. 1 to 6, unless otherwise specifically described.

In the inter-chip connection region CR, the first protective layer 280 may be configured as a first pattern P1′ by a groove Ga in the second direction Y, and the first pattern P1′ may be configured to cover two or two columns of through-via structures 350A, respectively. If necessary or desired, a groove in the first direction X may be additionally formed (see FIGS. 7A to 7C). Unlike the previous embodiment, the second protective layer 290 may be formed so as to be connected to each other along the upper surface and the side surface of the first pattern P1′. The second protective layer 290 may form a certain pattern together with the first protective layer 280, but may not be isolated from each other. In this case, since the first and second protective layers 280, 290 are isolated by small areas into blocks, the thermal stress generated in the contact area with the dam 560 in FIG. 8 may be reduced.

The first and second protective layers 280, 290 according to some example embodiments may be formed by forming the first protective layer 280 on the upper surface of the first chip 100, then performing an etching process to separate the first protective layer 280 into a desired first pattern P1′ in the inter-chip connection region CR, and then conformally forming the second protective layer 290 on the first protective layer 280 and the microlens layer 280L.

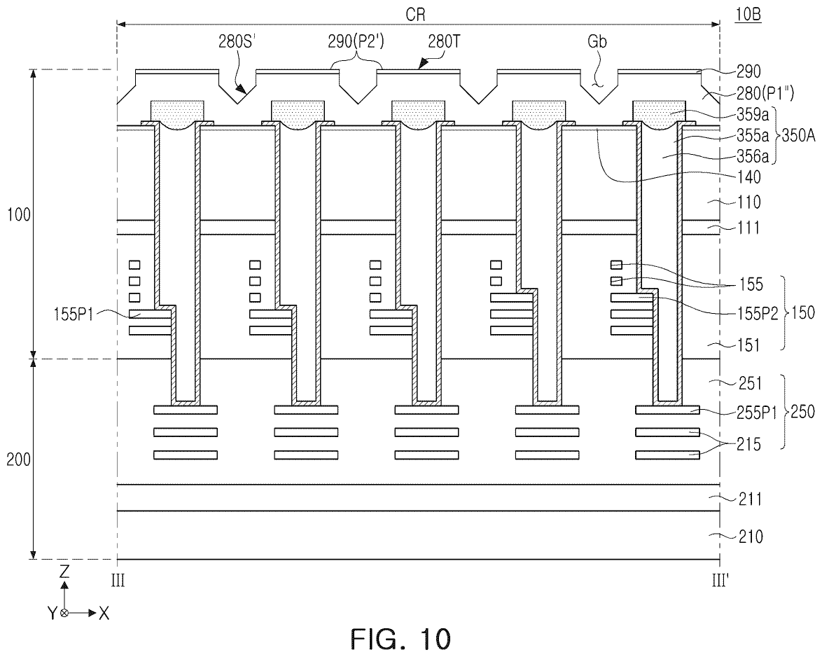

Referring to FIG. 10, an image sensor 10B according to some example embodiments may be understood to have a structure similar to that of the image sensor 10 illustrated in FIGS. 1 to 6, in detail, FIG. 4, except that the first protective layer 280 is composed of a first pattern P1″ that covers one or one column of through-via structures 350A in the inter-chip connection region CR, the first pattern P1″ is partially isolated, and the second protective layer 290 is provided as a second pattern P2′ corresponding to the upper surface of the first pattern P1″. In addition, the components of some example embodiments may be understood by referring to the description of the same or similar components of the image sensor 10 illustrated in FIGS. 1 to 6, unless otherwise specifically described.

In the inter-chip connection region CR, the first protective layer 280 may be configured as a first pattern P1″ by a groove Gb in the second direction Y, and the first pattern P1″ may be configured to cover one or more column of through-via structures 350A, respectively. The groove Gb may have a depth that partially isolates the first patterns P1′ without completely separating the first patterns.

In addition, the second protective layer 290 may be formed to have a second pattern P2′ corresponding to the upper surface 280T of the first pattern P1″. In some example embodiments, the second pattern P2′ may not extend to the side surface 280S′ of the first pattern P1″ exposed by the groove Gb.

The first and second protective layers 280, 290 according to some example embodiments may be formed by forming a first protective layer 280 having a flat upper surface on the upper surface of the first chip 100, then conformally forming a second protective layer 290 on the first protective layer 280 and the microlens layer 280L, and then etching a portion of the second protective layer 290 and the first protective layer 280 in the inter-chip connection region CR.

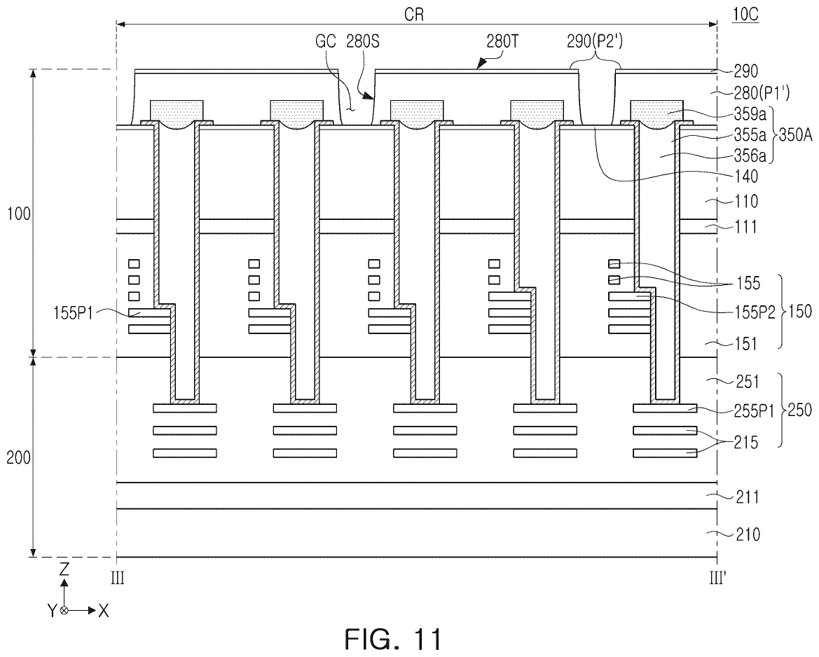

Referring to FIG. 11, an image sensor 10C according to some example embodiments may be understood to have a structure similar to that of the image sensor 10 illustrated in FIGS. 1 to 6, in detail, FIG. 4, except that the first protective layer 280 is configured as a first pattern P1′ covering two or two columns of through-via structures 350A in the inter-chip connection region CR, and the second protective layer 290 is provided as a second pattern P2′ corresponding to the upper surface of the first pattern P1′. In addition, the components of some example embodiments may be understood by referring to the description of the same or similar components of the image sensor 10 illustrated in FIGS. 1 to 6, unless otherwise specifically described.

In the inter-chip connection region CR, the first protective layer 280 may be configured as a first pattern P1′ by a groove Gc in the second direction Y, and the first The pattern P1′ may be configured to cover two or more columns of through-via structures 350A, respectively. The groove Gc may have a depth that completely isolates the first patterns P1′.

The second protective layer 290 may be formed to have a second pattern P2′ corresponding to the upper surface 280T of the first pattern P1′. In some example embodiments, the second pattern P2′ may not extend to the side surface 280S of the first pattern P1″ exposed by the groove Gc.

The first and second protective layers 280, 290 according to some example embodiments may be formed by forming a first protective layer 280 having a flat upper surface on the upper surface of the first chip 100, then conformally forming a second protective layer 290 on the first protective layer 280 and the microlens layer 280L, and then performing an etching process to completely isolate the second protective layer 290 and the first protective layer 280 together in the inter-chip connection region CR.

Referring to FIG. 12, an image sensor 10D according to some example embodiments may be understood to have a structure similar to the image sensor 10 illustrated in FIGS. 1 to 6, in detail, FIG. 4, except that the light-blocking filter layer 165 extends to the inter-chip connection region CR and the first protective layer 280 is configured as a first pattern P1′ covering two or two columns of through-via structures 350A in the inter-chip connection region CR. In addition, the components of some example embodiments may be understood by referring to the description of the same or similar components of the image sensor 10 illustrated in FIGS. 1 to 6 unless otherwise specifically described.

In some example embodiments, a light-blocking filter layer 165 located in a light-blocking region (see “OB” in FIG. 3) may extend to the inter-chip connection region CR. The light-blocking filter layer 165 may be formed on the surface insulating layer 140 to cover a plurality of through-via structures 350A.

The first protective layer 280 may be formed as a first pattern P1′ by a groove Gd in the second direction Y, and the first pattern P1′ may be formed to cover two or two columns of through-via structures 350A, respectively. Similar to some example embodiments described with reference to FIG. 4, the second protective layer 290 may be formed along the upper surface and side surfaces of the first pattern P1′.

As set forth above, by isolating first and second protective layers into multiple patterns in an inter-chip connection region of an image sensor, the influence of thermal stress may be reduced or significantly reduced, thereby effectively preventing or reducing damage such as cracks.

While some example embodiments have been illustrated and described above, it will be apparent to those skilled in the art that modifications and variations could be made without departing from the scope of inventive concepts as defined by the appended claims. Furthermore example embodiments are not necessarily mutually exclusive with one another. For example, some example embodiments may include one or more features described with reference to one or more figures, and may also include one or more other features described with reference to one or more other figures.

What is claimed is:

1. An image sensor comprising:
a first chip including a pixel array region, a pad region, and an inter-chip connection region between the pixel array region and the pad region;
a second chip on a lower surface of the first chip;
a plurality of through-via structures extending into the second chip by penetrating through the first chip in the inter-chip connection region of the first chip;
a surface insulating layer on the first chip;
color filters on the surface insulating layer within the pixel array region of the first chip;
a microlens layer including microlenses on the color filters;
a first protective layer on at least the inter-chip connection region of the first chip, and having a plurality of first patterns each covering at least one of the plurality of through-via structures; and
a second protective layer on the microlens layer and the first protective layer, and having a plurality of second patterns respectively positioned on the plurality of first patterns in the inter-chip connection region of the first chip.

2. The image sensor of claim 1, wherein the first protective layer is connected to the microlens layer and includes a same material as a material of the microlens layer.

3. The image sensor of claim 1, wherein
the pad region includes a plurality of pads disposed therein, and
the first protective layer extends over the pad region and has openings exposing the plurality of pads.

4. The image sensor of claim 1, wherein in a planar view the plurality of through-via structures are arranged in a first direction and a second direction intersecting the first direction.

5. The image sensor of claim 4, wherein the plurality of first patterns and the plurality of second patterns are isolated by grooves along at least one of the first direction or the second direction.

6. The image sensor of claim 4, wherein the plurality of first patterns and the plurality of second patterns are isolated by first grooves along the first direction and second grooves along the second direction.

7. The image sensor of claim 1, wherein the plurality of first patterns are configured to cover two or more adjacent through-via structures among the plurality of through-via structures.

8. The image sensor of claim 1, wherein the plurality of first patterns are configured to cover one through-via structure among the plurality of through-via structures.

9. The image sensor of claim 1, wherein the plurality of second patterns are respectively disposed on upper surfaces of the plurality of first patterns and extend to portions of side surfaces adjacent to the upper surfaces.

10. The image sensor of claim 1, wherein the plurality of second patterns are disposed on upper surfaces of the plurality of first patterns and do not extend to side surfaces adjacent to the upper surfaces.

11. The image sensor of claim 1, wherein the plurality of first patterns have patterns isolated from each other.

12. The image sensor of claim 11, wherein the plurality of second patterns have patterns isolated from each other, and cover upper and side surfaces of the plurality of first patterns, respectively.

13. The image sensor of claim 1, wherein the first protective layer has a thickness greater than a thickness of the second protective layer.

14. An image sensor comprising:
a first substrate including a pixel array region in which photoelectric conversion devices are arranged, a pad region, and an inter-chip connection region between the pixel array region and the pad region, and having a first surface including a light-receiving surface of the photoelectric conversion devices, and a second surface opposite to the first surface;
a first interconnection structure on the second surface of the first substrate and including a first wiring and a first inter-wiring insulating film;
a second substrate on the first interconnection structure and including a third surface opposite to the second surface and a fourth surface opposite to the third surface;
a second interconnection structure on the third surface of the second substrate, contacting the first interconnection structure, and including a second wiring and a second inter-wiring insulating film;
a plurality of through-via structures penetrating through the first substrate and the first interconnection structure, extending into the second interconnection structure and electrically connected to the second wiring, the plurality of through-via structures in the inter-chip connection region;
a surface insulating layer on the first surface of the first substrate;
color filters on the surface insulating layer within the pixel array region of the first substrate;
a microlens layer including microlenses on the color filters;
a first protective layer integrated with the microlens layer and extending over the inter-chip connection region and the pad region, and having a plurality of first patterns each covering at least one of the plurality of through-via structures; and
a second protective layer disposed on the microlens layer and the first protective layer, and having a plurality of second patterns respectively positioned on the plurality of first patterns and isolated from each other.

15. The image sensor of claim 14, wherein
the plurality of through-via structures are arranged in a first direction and a second direction intersecting the first direction in a planar view, and
the plurality of through-via structures are arranged such that an interval therebetween in the second direction is greater than an interval in the first direction, and the plurality of first patterns are isolated by grooves along the first direction.

16. The image sensor of claim 14, wherein the second protective layer has a thickness smaller than a thickness of the first protective layer.

17. The image sensor of claim 16, wherein
the plurality of first patterns have patterns isolated from each other, and
the plurality of second patterns are respectively arranged on upper surfaces of the plurality of first patterns, and extend to portions of side surfaces adjacent to the upper surfaces.

18. The image sensor of claim 14, wherein
the first substrate further includes a light-blocking region between the pixel array region and the inter-chip connection region, and
the image sensor further includes a light-blocking pattern between the surface insulating layer and the first protective layer, the light-blocking pattern on the light-blocking region.

19. An image sensor comprising:
a first chip including a pixel array region, a pad region, and an inter-chip connection region between the pixel array region and the pad region;
a second chip on a lower surface of the first chip;
a plurality of through-via structures extending into the second chip by penetrating through the first chip in the inter-chip connection region of the first chip;
a surface insulating layer on the first chip;
color filters on the surface insulating layer within the pixel array region of the first chip;
a microlens layer including microlenses on the color filters;
a first protective layer on the inter-chip connection region and the pad region of the first chip; and
a second protective layer on the microlens layer and the first protective layer,
wherein in the inter-chip connection region, the first and second protective layers have a plurality of patterns each covering at least one of the plurality of through-via structures.

20. The image sensor of claim 19, wherein the plurality of patterns are isolated by a groove having a depth that penetrates the second protective layer and extends to a portion of the first protective layer.
